(19) United States
(12) Patent Application Publication
(10) Pub. No.: US 2026/0110725 A1
(43) Pub. Date: Apr. 23, 2026

(54) METHOD FOR DETERMINING AN INSULATION RESISTANCE AND A DISCHARGE CAPACITANCE OF AN UNEARTHED POWER SUPPLY SYSTEM

(71) Applicant: BENDER GMBH & CO. KG, Gruenberg (DE)

(72) Inventor: Michael SYLLA, Schwalmtal (DE)

(21) Appl. No.: 19/161,026

(22) PCT Filed: Mar. 19, 2024
(86) PCT No.: PCT/EP2024/057305

§ 371 Date: Aug. 29, 2025

(30) Foreign Application Priority Data
Mar. 29, 2023 (DE) 10 2023 107 987.5

(51) Int. Cl. G01R 31/14

(52) U.S. Cl. CPC G01R 31/14

(57) ABSTRACT

A method for determining an insulation resistance and a discharge capacitance to earth of an unearthed DC power supply system, wherein a linear differential equation is implemented with a measured voltage as a function of the measurement voltage and the grid voltage and with grid parameters formed from the shunts (RM), from the insulation resistances to be determined and from the discharge capacitances to be determined. N linear differential equations are used to implement a measured value equation system with the sample sequences and the grid parameters for k=1, 2 to N measurement times with the sampling period T.

The invention relates to a method for determining an insulation resistance and a leakage capacitance of an ungrounded power supply system according to the preamble of claim 1.

For higher requirements to the operational, fire and touch safety, the network configuration of an ungrounded power supply system is used, which is also referred to as insulated network (IT network) or as IT power supply system (French: isolé terre—IT). In this type of power supply system, the active parts are isolated from the ground potential-against “ground”. The advantage of these networks is that the function of the connected electrical consumers is not impeded during an insulation fault (first fault), such as an accidental ground of an active conductor of the ungrounded power supply system, since a closed circuit cannot form between the active conductor of the network and ground because of the ideally infinitely large impedance value. As a real component (real part) in a parallel circuit having a leakage capacitance as an imaginary part, an electric resistance in relation to the ground potential (against ground) in this context forms the complex-valued insulation impedance of the ungrounded power supply system.

The electric resistance of the ungrounded power supply system against the ground potential, referred to as insulation resistance, must therefore be monitored using a standardized insulation monitoring device (IMD), as another possible fault at another active conductor (second fault) could cause a fault loop, and the resulting flowing fault current in conjunction with an overcurrent protective device would result in a shutdown of the installation including an operational standstill.

Aside from passive insulation monitoring devices, which use a line voltage of the ungrounded power supply system as a driving source for a measuring current to detect an insulation fault, actively operating insulation monitoring devices are known from the state of the art. They have a measuring path which extends between one or more active conductors of the ungrounded power supply system and the ground potential and comprises an internal measuring-voltage generator. A measuring voltage generated by the measuring-voltage generator actively drives a measuring current which flows back to the measuring path via the active conductor(s) and via the insulation resistance and the leakage impedance and there causes a voltage drop at a measured resistance switched in series to the measuring-voltage generator. The voltage drop registered via the measured resistance is used for determining the insulation resistance and the leakage impedance.

Active methods are known which superpose a square-shaped measuring voltage consisting of consecutive measuring pulses on the ungrounded power supply system to be monitored. A reliable computation of the insulation resistance is only possible, however, when the measuring voltage has settled, which may take up to several minutes for larger leakage capacitances.

Furthermore, undesired yet unavoidable line voltage changes can interfere with the measurement. High-frequency line voltage changes (greater than several Hertz) can be removed by filters. However, low-frequency line voltage changes of only a few Hertz are problematic because they impede the identification of the settling and falsify the computed insulation resistance. Large voltage changes in the low-frequency domain can therefore make a measurement impossible because the measuring voltage does not become settled.

Patent EP 2 433 147 B1 discloses a method by means of which the insulation resistance can be identified before the measured voltage at a measured resistance has reached a settled state. In this case, the settling process is predicted by a mathematical model whose parameters are iteratively adapted until the theoretical and the measured curve of the measured voltage coincide as well as possible. The insulation resistance can then be computed based on the model parameters. Interfering line voltage changes are compensated by filters and difference formation of two consecutive measured pulses. However, the elimination of low-frequency line voltage changes also appears problematic. A disadvantage continues to be the time-intensive computation of the matrix inversion for determining the model parameters.

The object of the invention at hand is the ability to conduct as quick, reliable and robust a measurement of the insulation resistance and the leakage capacitance as possible in an ungrounded power supply system; in particular, the interfering factor of low-frequency line voltage changes in conjunction with an implementation efficient from a computational standpoint is to be minimized.

This object is attained by a method having the features of claim 1.

Based on the state of the art, a measuring voltage in series is coupled to a measured resistance in a unipolar or bipolar manner between one of the active conductors in each instance and a voltage drop—caused by a measuring current driven by the measuring voltage—is measured via the corresponding measured resistance.

In DC power supply systems, a bipolar coupling has proven purposeful, as this solves the problem of low-frequency line voltage changes particularly effectively. In AC and 3AC power supply systems, a unipolar coupling is sufficient, as the line frequency can be removed by filtering.

From the voltage curves of the measuring voltage, the line voltage and the voltage drop at the corresponding measured resistances, time and value-discrete sample sequences of the measuring voltage, the line voltage and a measured voltage are generated.

The continuous signal curves of the line voltage (nominal voltage of the ungrounded power supply system) and the applied measuring voltage generated in a measuring-signal generator and the captured voltage drops at the measured resistances are converted to time and value-discrete signals by sampling devices (analog-to-digital converter-A/D converter) in order to make them accessible as sample sequences for digital signal processing.

The thus generated sample sequences form input and output variables of a functional equivalent circuit diagram of the observed ungrounded power supply system having insulation monitoring, its mathematical description being provided by physical laws (Ohm's laws) and Kirchhoff's laws in linear networks (current-voltage relationships).

Based on these laws, a linear difference equation is implemented in which a measured voltage (corresponding to a measured voltage drop for a unipolar coupling or the sum of the measured voltage drops for bipolar couplings) can be expressed as a function of the measuring voltage and the line voltage, network parameters of the ungrounded power supply system to be identified representing coefficients of the linear difference equation. In this context, the network parameters are formed from the measured resistances, from the insulation resistances to be determined and from the leakage capacitances to be determined. For computational simplification, the resistance values are expressed by conductance values.

By incorporating the line voltage in the current-voltage relationships of the linear difference equation, it is not necessary to remove the line voltage from the measuring voltage, such as by filtering or other signal-processing measures. The circuitry effort is advantageously reduced and the measuring method becomes interference-proof.

Moreover, a faster and continuous measurement for slow, low-frequency changes of the line voltage is possible. This is of advantage in particular in PV installations, as their DC line voltage fluctuates as a function of the intensity of sun radiation.

In comparison to the methods prevailing in the state of the art, in which a stable line voltage and a settled measuring current is presumed for identifying the insulation resistance, it is possible to continue uninterrupted measurements using the method according to the invention.

In a following step, a measured-value equation system of N linear difference equations is implemented for k=1, 2 to N measuring points in time having the sample period T from the sample sequences of the measuring voltage, the line voltage, the measuring voltage and the network parameters.

An overdetermined measured value equation system is derived for N>4 measuring points in time. As a general rule, no solution vector, presently therefore no set of network parameters (coefficient vectors) which precisely solves all N linear difference equations, exists for this overdetermined measured-value equation system.

For this reason, estimated network parameters are computed as approximate solutions of the measured-value equation system, a sum of the squared residuals between the (actual) network parameters and the estimated network parameters being minimized.

The estimated network parameters are then deemed optimal in the sense of the approximate solution when the sum of the squared residuals resulting from the remaining (residual) fault between the actual network parameters and the estimated network parameters becomes minimal.

This minimization problem or compensation problem is solved by minimizing the sum of the squared residuals by means of QR decomposition of a measured-value matrix, which characterizes the measured-value equation system, the QR decomposition being computed recursively.

The measured-value equation system comprising N linear difference equations can be written as a measured-value matrix equation in which the sample sequence of the measuring voltage (measured-value vector) is yielded as a factor from the multiplication of the measured-value matrix by the coefficient vector (network-parameter vector). The elements of the measured-value matrix correspond to the samples of the measuring voltage, the line voltage and—owing to the iterative nature of difference equations—preceding samples of the measured voltage.

A matrix inversion requiring much computation and required for solving the minimization problem by means of a gradient method is avoided by a QR decomposition of the measured-value matrix. Under unfavorable conditions, such as if the measuring voltage or the line voltage were zero, this would lead to zero columns and consequently to a non-invertible matrix. In this case, a matrix inversion in contrast to a QR decomposition would not be possible.

The QR decomposition in contrast is significantly more robust numerically and allows a computation of the estimated network parameters even for a poorly conditioned measured-value matrix. The computation of the estimated network parameters as intended by the invention reacts sensitively to faulty measured data and rounding errors, thus making it more precise.

Starting from a geometric interpretation of the minimization problem, the error squares can be viewed as squares of the Euclidian norm. This allows ascribing the minimization problem to a QR matrix equation by applying a QR decomposition of the measured-value matrix. In contrast to the measured-value matrix equation, which represents the measured-value equation system consisting of the difference equations, the (matrix) equation which solves the minimization problem and presents a result vector as a matrix product from an upper triangular matrix and an estimated network-parameter vector is presently described as the QR matrix equation.

A solution for the estimated network-parameter vector is identified by back substitution using the previously (recursively) computed upper triangular matrix R of the QR decomposition and (recursively) determined result vector of the QR matrix equation.

According to the invention, the QR decomposition is computed recursively. In this context, the results, which are each computed in a method cycle, from the QR decomposition—the upper triangular matrix R and the results vector of the QR matrix equation—are updated in the following cycle by taking into consideration currently available measured values, meaning a step-by-step approximation to the actual network parameters takes places.

The storage need and the computation effort are significantly reduced by the recursive computation, as only a currently available measured-value set is processed. This means an efficient implementation on a microcontroller is possible.

Aside from the advantage that the recursive QR decomposition requires little storage space and computation time, a quick adaptation to changing (actual) network parameters takes place. If the currently effective insulation resistance or the leakage capacitance changes, the measurement and the computations can be easily pursued owing to the continuous adaptation.

The corresponding, conductor-related insulation resistance and the corresponding leakage capacitance are computed from the estimated network parameters.

As would be common in the state of the art, the insulation resistances and the leakage capacitances are not computed directly from the voltage drops measured via the measuring resistances but from the estimated network parameters. It is therefore not strictly necessary for the measured voltage to have reached a settled state in order to be able to reliably conduct computations.

On the one hand, the method according to the invention allows quickly identifying the insulation resistance and the leakage capacitance and, on the other hand, more freedom is available when selecting the signal shape of the measuring voltage. Thus, it is possible, for example, to also select a sine-shaped measuring voltage or a mixture of sine-shape voltage curves from differing frequencies as measuring signal.

The method steps are continuously repeated with the correspondingly computed, estimated network parameters while taking into consideration the samples available for the current measuring point in time.

Therefore, a running adaptation to the currently available insulation state of the ungrounded power supply system takes place, a resource-efficient and quick identification of the insulation resistance and the leakage capacitance being ensured owing to the recursive computation.

In another embodiment, the linear difference equation is derived by transforming a linear algebraic equation in the frequency domain in a temporally continuous difference equation and its time-discrete implementation, the linear algebraic equation describing the current-voltage relationships.

The starting point of the implementation of the linear difference equation is a description of the current-voltage relationships in the frequency domain (image domain) via a linear algebraic equation, the current-voltage relationships being yielded from the equivalent circuit diagram of the observed ungrounded power supply system having insulation monitoring. Preferably, the Laplace transform is used for describing the relationships in the frequency domain. Transferred to the time domain, this results in a time-discrete differential equation, and the linear difference equation follows from the subsequent time-discretization. Its application for consecutive measuring points in time (samples) yields the measured-value equation system representable as the measured-value matrix equation and having the measured-value matrix for determining the network parameters.

Preferably, the recursive QR decomposition is carried out based on a recursion matrix.

An initial matrix having suitable initial parameters for the upper triangular matrix of the QR decomposition and for the result vector of the QR matrix equation is enhanced by the current measured-value set to a recursion matrix in an initialization phase of the method. In each subsequent method cycle, this measured-value set is replaced by the corresponding current measured-value set. The upper triangular matrix R and the result vector are iteratively computed anew for each method cycle while taking into consideration the corresponding current measured set.

Furthermore, the QR decomposition is carried out by means of Givens rotation.

By means of the method of Givens Rotations for computing the upper triangular matrix, rotation matrices are computed in each method cycle in order to generate zero entries in the recursion matrix in a targeted manner. Consequently, an updated upper triangular matrix R and an updated result vector are available at the end of each method cycle, the QR matrix equation being able to be solved via back substitution using the updated upper triangular matrix R and the updated result vector, thus being able to determine the estimated network-parameter vector.

Advantageously, an upper triangular matrix and a result vector are weighted using a Forgetting Factor in the recursive QR decomposition.

The upper triangular matrix R and the result vector of the QR matrix equation are multiplied by a factor—the Forgetting Factor—in order to introduce a weighting of the measured values.

The forgetting Factor has the effect that current measured values are weighted higher than past measured values. It has a typical value ranging between 0.95 and 1. The larger the factor is, the more older measured values are taken into account in the computation. Hence, parameter changes are identified more slowly; however, short-term interferences are better filtered. Vice versa, a smaller factor allows a quicker identification of a parameter change with the disadvantage that the measurement becomes more prone to interferences. The recursive computation using the Forgetting Factor allows following such changes.

Further advantageous embodiments are derived from the following description and the drawings, which describe a preferred embodiment of the invention using examples.

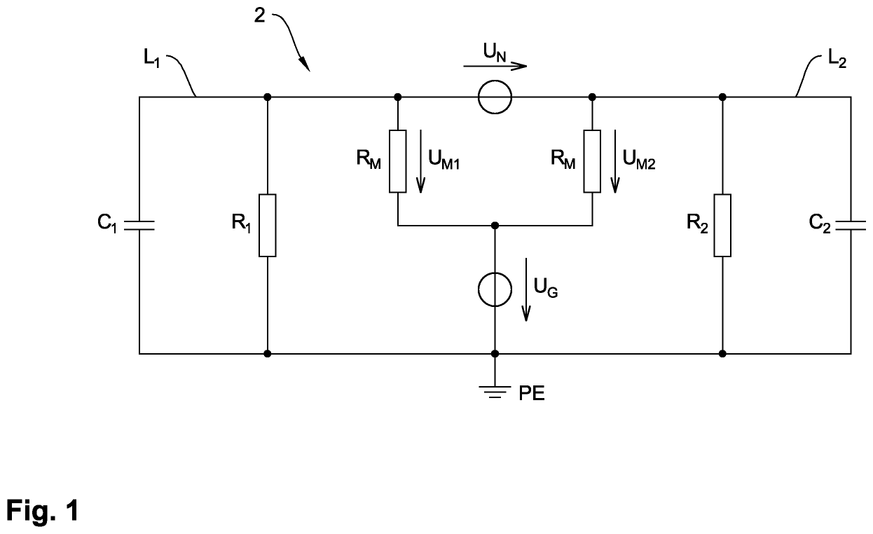

FIG. 1 shows a functional equivalent circuit diagram of an ungrounded power supply system having insulation monitoring;

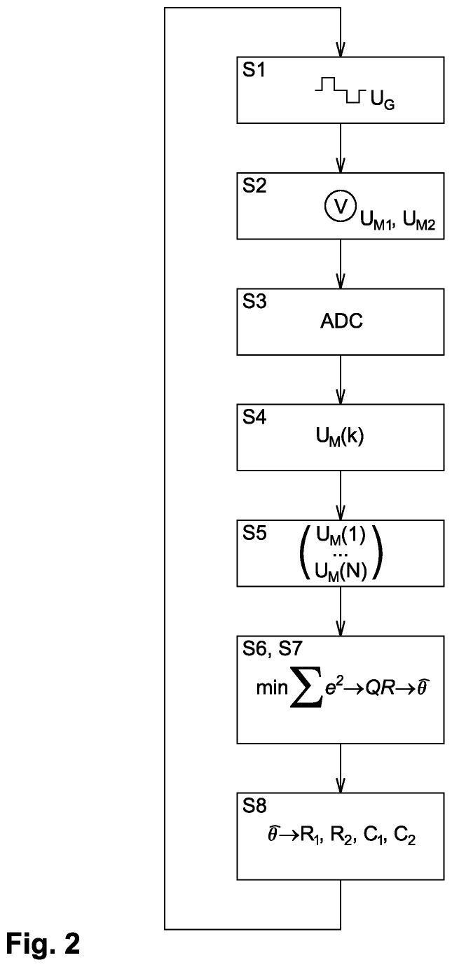

FIG. 2 shows a sequence diagram of the method according to the invention;

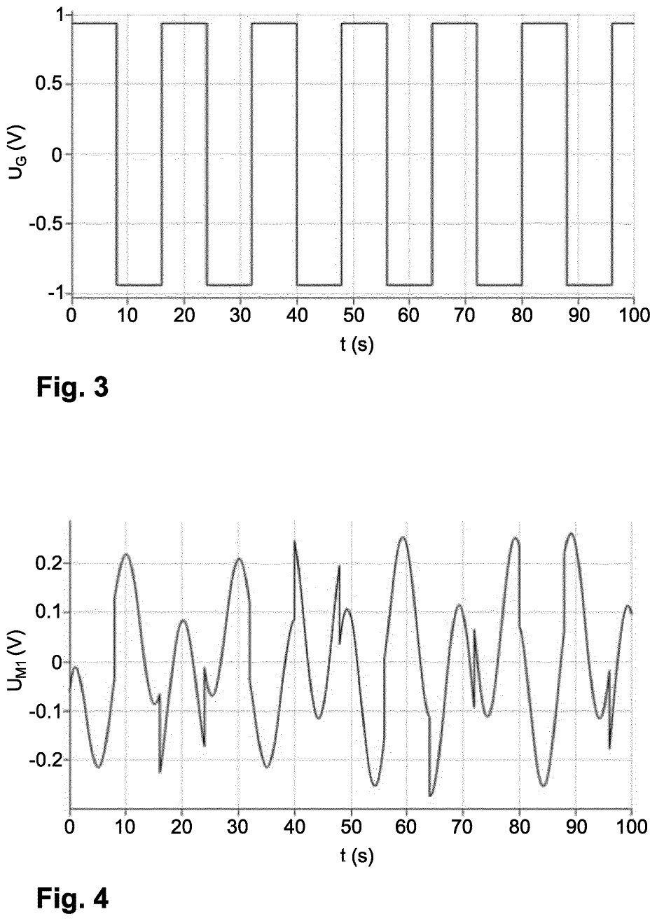

FIG. 3 shows a square-pulse-shaped measuring voltage;

FIG. 4 shows a voltage drop measured via a measured resistance when a line voltage changes;

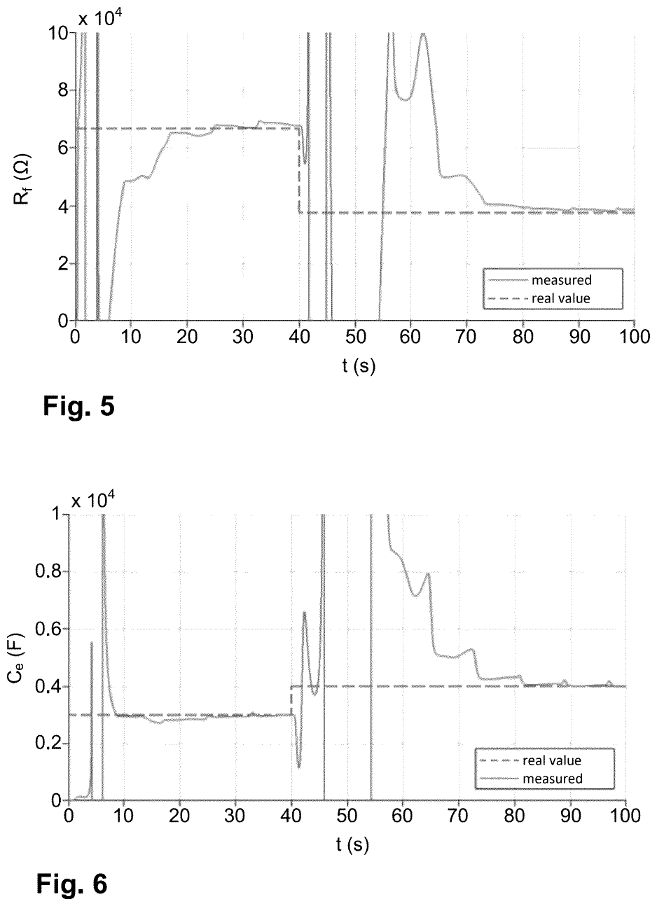

FIG. 5 shows a temporal progression of a computed insulation resistance; and

FIG. 6 shows a temporal progression of a computed leakage capacitance.

FIG. 1 shows a functional equivalent circuit diagram of an ungrounded power supply system 2 to be monitored and having line voltage U_{N}.

The method according to the invention can be applied in both a DC power supply system and in a single-phase or multiphase AC power supply system, the measuring voltage U_{G} being coupled exemplarily in this instance to two active conductors L₁, L₂ in a DC power supply system in a bipolar manner.

An insulation impedance effective in each instance between active conductors L₁, L₂ and ground PE is shown via an insulation resistance R₁, R₂ (real part of the insulation impedance) in a parallel circuit having a leakage capacitance C₁, C₂ (imaginary part of the insulation impedance).

For insulation monitoring, a measuring-voltage generator generates a measuring voltage U_{G}, which drives a measuring current flowing via active conductors L₁, L₂, via insulation resistance R₁, R₂ and via leakage capacitances C₁, C₂ and causing a voltage drop U_{M1}, U_{M2} at measured resistances R_{M}, voltage drop U_{M1}, U_{M2} being measured and evaluated for determining insulation resistances R₁, R₂ and leakage capacitances C₁, C₂.

In practice, measuring voltage U_{G} is coupled via a series connection having a high-impedance coupling resistance and a low-impedance measured resistance. For computational simplicity, both resistances have been summarized to corresponding measured resistance R_{M}.

FIG. 2 describes a sequence diagram of the method according to the invention.

Following an initialization phase of the method in which initial values of the parameters for the upper triangular matrix of the QR decomposition and for the result vector of the QR matrix equation have been set, measuring voltage U_{G} is switched in steps S1 and S2 with the measurement of the corresponding voltage drop U_{M1}, U_{M2} settling via measured resistances R_{M} owing to the measuring current.

By sampling and quantizing, time and value-discrete sample sequences U_{G}(k), U_{N}(k), U_{M}(k) of measuring voltage U_{G}, line voltage U_{N} and voltage drops U_{M1}, U_{M2} are generated in step S3.

With the current-voltage relationships derived on the basis of the functional equivalent circuit diagram, a linear difference equation is implemented in step S4.

Starting from a description in the frequency domain via the algebraic equation for measured voltage U_{M} (this is composed of the sum of voltage drops U_{M1}, U_{M2} because of the exemplarily viewed bipolar coupling and would correspond to only voltage drop U_{M1} or U_{M2} for an only unipolar coupling)

$${U}_{M 1} ( s ) + {U}_{M 2} ( s ) = {U}_{M} ( s ) = - 2 \frac{s + \frac{{G}_{1} + {G}_{2}}{{C}_{1} + {C}_{2}}}{s + \frac{{G}_{1} + {G}_{2} + 2 {G}_{M}}{{C}_{1} + {C}_{2}}} {U}_{G} ( s ) + \frac{{C}_{2} - C 1}{{C}_{1} + {C}_{2}} \cdot \frac{s + \frac{{G}_{2} - {G}_{1}}{{C}_{2} - {C}_{1}}}{s + \frac{{G}_{1} + {G}_{2} + 2 {G}_{M}}{{C}_{1} + {C}_{2}}} {U}_{N} ( s ) \qquad ( equation 1 )$$

the time-continuous differential equation follows from the transfer of the measured voltage U_{M} to the time domain, and the linear difference equation is yielded from the subsequent time discretization having index k of sample sequences and sample period T; in the linear difference equation, measured voltage U_{M}(k) a function of measuring voltage U_{G}(k) and line voltage U_{N}(k) can be expressed as

$${U}_{M} ( k ) = - 2 \frac{{G}_{1} + {G}_{2} + \frac{1}{T} ( {C}_{1} + {C}_{2} )}{{G}_{1} + {G}_{2} + 2 {G}_{M} + \frac{1}{T} ( {C}_{1} + {C}_{2} )} {U}_{G} ( k ) - \frac{{G}_{1} - {G}_{2} + \frac{1}{T} ( {C}_{1} - {C}_{2} )}{{G}_{1} + {G}_{2} + 2 {G}_{M} + \frac{1}{T} ( {C}_{1} + {C}_{2} )} {U}_{N} ( k ) + \frac{\frac{1}{T} ( {C}_{1} - {C}_{2} )}{{G}_{1} + {G}_{2} + 2 {G}_{M} + \frac{1}{T} ( {C}_{1} + {C}_{2} )} {U}_{N} ( k - 1 ) + \frac{\frac{1}{T} ( {C}_{1} + {C}_{2} )}{{G}_{1} + {G}_{2} + 2 {G}_{M} + \frac{1}{T} ( {C}_{1} + {C}_{2} )} ( {U}_{M} ( k - 1 ) + 2 {U}_{G} ( k - 1 ) ) \qquad ( equation 2 )$$

In the matrix notation, the following is derived:

$${U}_{M} ( k ) = ( \begin{matrix}{U}_{G} ( k ) & {U}_{N} ( k ) & {U}_{N} ( k - 1 ) & {U}_{M} ( k - 1 ) + 2 {U}_{G} ( k - 1 )\end{matrix} ) \cdot ( \begin{matrix}- 2 \frac{{G}_{1} + {G}_{2} + \frac{1}{T} ( {C}_{1} + {C}_{2} )}{{G}_{1} + {G}_{2} + 2 {G}_{M} + \frac{1}{T} ( {C}_{1} + {C}_{2} )} \\ - \frac{{G}_{1} - {G}_{2} + \frac{1}{T} ( {C}_{1} - {C}_{2} )}{{G}_{1} + {G}_{2} + 2 {G}_{M} + \frac{1}{T} ( {C}_{1} + {C}_{2} )} \\ \frac{\frac{1}{T} ( {C}_{1} - {C}_{2} )}{{G}_{1} + {G}_{2} + 2 {G}_{M} + \frac{1}{T} ( {C}_{1} + {C}_{2} )} \\ \frac{\frac{1}{T} ( {C}_{1} + {C}_{2} )}{{G}_{1} + {G}_{2} + 2 {G}_{M} + \frac{1}{T} ( {C}_{1} + {C}_{2} )}\end{matrix} ) \qquad ( equation 3 )$$

For k=1, 2 to N measuring points in time, the implementation of an over-determined measured-value equation system is yielded therefrom:

$$( \begin{matrix}\begin{matrix}{U}_{M} ( 1 ) \\ ⋮\end{matrix} \\ {U}_{M} ( N )\end{matrix} ) = ( \begin{matrix}{U}_{G} ( 1 ) & {U}_{N} ( 1 ) & {U}_{N} ( 0 ) & {U}_{M} ( 0 ) + 2 {U}_{G} ( 0 ) \\ ⋮ & ⋮ & ⋮ & ⋮ \\ {U}_{G} ( N ) & {U}_{N} ( N ) & {U}_{N} ( N - 1 ) & {U}_{M} ( N - 1 ) + 2 {U}_{G} ( N - 1 )\end{matrix} ) \cdot ( \begin{matrix}- 2 \frac{{G}_{1} + {G}_{2} + \frac{1}{T} ( {C}_{1} + {C}_{2} )}{{G}_{1} + {G}_{2} + 2 {G}_{M} + \frac{1}{T} ( {C}_{1} + {C}_{2} )} \\ - \frac{{G}_{1} - {G}_{2} + \frac{1}{T} ( {C}_{1} - {C}_{2} )}{{G}_{1} + {G}_{2} + 2 {G}_{M} + \frac{1}{T} ( {C}_{1} + {C}_{2} )} \\ \frac{\frac{1}{T} ( {C}_{1} - {C}_{2} )}{{G}_{1} + {G}_{2} + 2 {G}_{M} + \frac{1}{T} ( {C}_{1} + {C}_{2} )} \\ \frac{\frac{1}{T} ( {C}_{1} + {C}_{2} )}{{G}_{1} + {G}_{2} + 2 {G}_{M} + \frac{1}{T} ( {C}_{1} + {C}_{2} )}\end{matrix} ) \qquad ( equation 4 )$$

which can be written as a measured-value matrix equation having the measured-value vector y, measured-value matrix Ψ and network-parameter vector (coefficient vector) θ:

$$y = Ψ \cdot θ \qquad ( equation 5 )$$

Network-parameter vector θ consists of the elements θᵢ (network parameter), which can be formed from the network configuration variables to be determined G₁=1/R₁, G₂=1/R₂, C₁ and C₂ and from measured resistances R_{M}.

Since overdetermined equation systems generally do not have a solution, an approximation result is computed in step S6, a (residual) error e, which ideally only indicates the measuring noise, remaining in the approximation result. From network-parameter vector θ in equations (4) and (5), an estimated network-parameter vector \hat{θ} having estimated network parameters \hat{θ}ᵢ is thus yielded:

$$y = Ψ \cdot \hat{θ} + e \qquad ( equation 6 )$$

Estimated network parameters \hat{θ}ᵢ (elements of network-parameter vector \hat{θ}) are deemed optimal if the square sum of error e is minimal:

$${min}_{\hat{θ}} {\sum }_{k = 1}^{N} {e}_{k}^{2} = {min}_{\hat{θ}} {e}^{T} e \qquad ( equation 7 )$$

The result of this minimization problem by means of a gradient method demands a matrix inversion, whose computation can become numerically instable. To circumvent this matrix inversion, equation (7) is interpreted geometrically and viewed as a square of the Euclidean standard:

$${min}_{\hat{θ}} {e}^{T} e = {min}_{\hat{θ}} {‖ Ψ \hat{θ} - y ‖}_{2}^{2} \qquad ( equation 8 )$$

In step S7, the (complete/entire) QR decomposition is applied to measured value matrix Ψ with orthonormal matrix Q and an upper triangular matrix R, 0 being the zero matrix:

$$Ψ = Q ( \begin{matrix}R \\ 0\end{matrix} ) \qquad ( equation 9 )$$

Left-hand multiplication by Q^{T} yields Q^{T}Q=1 because of the orthonormality:

$${Q}^{T} Ψ = ( \begin{matrix}R \\ 0\end{matrix} ) \qquad ( equation 10 )$$

The multiplication of measured-value vector y can likewise be divided as:

$${Q}^{T} y = ( \begin{matrix}c \\ \tilde{c}\end{matrix} ) \qquad ( equation 11 )$$

wherein c is described as a result vector and vector \tilde{c} depicts the remaining error.

Since Q is orthonormal, the Euclidean standard does not change because of the left-hand multiplication by Q^{T}—the multiplication is length-preserving—and the expression in equation (8) to be minimized converts to

$${‖ Ψ \hat{θ} - y ‖}_{2}^{2} {‖ {Q}^{T} ( Ψ \hat{θ} - y ) ‖}_{2}^{2} = {‖ {Q}^{T} Ψ \hat{θ} - {Q}^{T} y ‖}_{2}^{2} = {‖ ( \begin{matrix}R \\ 0\end{matrix} ) \hat{θ} - ( \begin{matrix}c \\ \tilde{c}\end{matrix} ) ‖}_{2}^{2} = {‖ ( \begin{matrix}R \hat{θ} - c \\ 0 - \tilde{c}\end{matrix} ) ‖}_{2}^{2} = {\underbrace{{‖ R \hat{θ} - c ‖}_{2}^{2}}}_{= 0} + {‖ \tilde{c} ‖}_{2}^{2} \qquad ( equation 12 )$$

The expression

$${\underbrace{{‖ R \hat{θ} - c ‖}_{2}^{2}}}_{= 0} + {‖ \tilde{c} ‖}_{2}^{2}$$

in equation (12) possesses a minimum when the QR matrix equation

$$R \hat{θ} = c \qquad ( equation 13 )$$

is fulfilled. The estimated network-parameter vector \hat{θ} can then be easily determined by back substitution in light of the upper triangular matrix R and result vector c.

For computing R and c, a recursive method is used. As initial values, the unit matrix is chosen for R and adequate initial network parameters \hat{θ}ᵢ (0) are chosen for c. In an example of four network-parameter values to be estimated, the following matrix is yielded as a unit matrix:

$${Q}^{T} ( \begin{matrix}Ψ & y\end{matrix} ) = ( \begin{matrix}R & c\end{matrix} ) = ( \begin{matrix}1 & 0 & 0 & 0 & {\hat{θ}}_{1} ( 0 ) \\ 0 & 1 & 0 & 0 & {\hat{θ}}_{2} ( 0 ) \\ 0 & 0 & 1 & 0 & {\hat{θ}}_{3} ( 0 ) \\ 0 & 0 & 0 & 1 & {\hat{θ}}_{4} ( 0 )\end{matrix} ) \qquad ( equation 14 )$$

This unit matrix is now enhanced by a first measured-value set (ψ^{T} y′) and leads to the recursion matrix

$$( \begin{matrix}R & c \\ {ψ}^{T} & {y}^{′}\end{matrix} ) = ( \begin{matrix}1 & 0 & 0 & 0 & {\hat{θ}}_{1} ( 0 ) \\ 0 & 1 & 0 & 0 & {\hat{θ}}_{2} ( 0 ) \\ 0 & 0 & 1 & 0 & {\hat{θ}}_{3} ( 0 ) \\ 0 & 0 & 0 & 1 & {\hat{θ}}_{4} ( 0 ) \\ {ψ}_{1} & {ψ}_{2} & {ψ}_{3} & {ψ}_{4} & {y}^{′}\end{matrix} ) \qquad ( equation 15 )$$

By means of Givens rotation, zero elements can be generated in a targeted manner by repeated left-hand multiplication by rotation matrices G_{i,j}. If the element (i,j) is to be zeroed, the rotation then only has an influence on the lines i and j. Consequently, the recursion matrix from equation (15) can be transformed to the form

$$( \begin{matrix}R & c \\ {ψ}^{T} & {y}^{′}\end{matrix} ) \to ( \begin{matrix}{R}^{′} & {c}^{′} \\ {0}^{T} & \tilde{c}\end{matrix} ) \qquad ( equation 16 )$$

thus yielding:

$${G}_{5 , 1} ( \begin{matrix}1 & 0 & 0 & 0 & {\hat{θ}}_{1} ( 0 ) \\ 0 & 1 & 0 & 0 & {\hat{θ}}_{2} ( 0 ) \\ 0 & 0 & 1 & 0 & {\hat{θ}}_{3} ( 0 ) \\ 0 & 0 & 0 & 1 & {\hat{θ}}_{4} ( 0 ) \\ {ψ}_{1} & {ψ}_{2} & {ψ}_{3} & {ψ}_{4} & {y}^{′}\end{matrix} ) \to {G}_{5 , 2} ( \begin{matrix}* & * & * & * & * \\ 0 & 1 & 0 & 0 & {\hat{θ}}_{2} ( 0 ) \\ 0 & 0 & 1 & 0 & {\hat{θ}}_{3} ( 0 ) \\ 0 & 0 & 0 & 1 & {\hat{θ}}_{4} ( 0 ) \\ 0 & * & * & * & *\end{matrix} ) \to {G}_{5 , 3} ( \begin{matrix}* & * & * & * & * \\ 0 & * & * & * & * \\ 0 & 0 & 1 & 0 & {\hat{θ}}_{3} ( 0 ) \\ 0 & 0 & 0 & 1 & {\hat{θ}}_{4} ( 0 ) \\ 0 & 0 & * & * & *\end{matrix} ) \to {G}_{5 , 4} ( \begin{matrix}* & * & * & * & * \\ 0 & * & * & * & * \\ 0 & 0 & * & * & * \\ 0 & 0 & 0 & 1 & {\hat{θ}}_{4} ( 0 ) \\ 0 & 0 & 0 & * & *\end{matrix} ) \to ( \begin{matrix}* & * & * & * & * \\ 0 & * & * & * & * \\ 0 & 0 & * & * & * \\ 0 & 0 & 0 & * & * \\ 0 & 0 & 0 & 0 & \tilde{c}\end{matrix} ) \qquad ( equation 17 )$$

The initial values are iteratively replaced by a newly computed upper triangulation matrix R′ and a newly computed result vector c′. With newly computed upper triangulation matrix R′ and newly computed result vector c′, estimated network-parameter vector \hat{θ} according to QR matrix equation 13 can be determined by back substitution.

At the end of each method cycle, corresponding insulation resistance R₁, R₂ and corresponding leakage capacitance C₁, C₂ are computed from estimated network parameters \hat{θ}ᵢ in step S8.

By taking into consideration the line voltage in the description of the current-voltage relationships (obtained from the equivalent circuit diagram), it becomes possible to determine the insulation resistance and the leakage capacitance in a phase-segregated manner, i.e., separately for each conductor.

The distribution to the individual active conductors simplifies a fault location in the ungrounded DC power supply system.

On the basis of the recursion matrix shown in equations (15) and (16), the method cycle is continuously repeated with the following measured-value set (ψ^{T} y′) available at the current measuring point in time, with the newly computed upper triangulation matrix R′ and with the newly computed result vector c′.

In this context, prior to the following method cycle, the newly computed upper triangulation matrix R′ and the newly computed c′ can be multiplied by a forgetting factor \sqrt{λ} in order to attain a temporal weighting of the measured values.

FIG. 3 shows a square-pulse-shaped measuring voltage U_{G}, which is generated by the measuring-voltage generator and is superposed on ungrounded DC power supply system 2. As the maximal modulation amplitude is 1.2 V, measuring voltage U_{G} has an amplitude of approximately 1 V. The pulse width is 8 s.

FIG. 4 shows a voltage drop U_{M1} measured via a measured resistance R_{M} when line voltage U_{N} has a low-frequency line-voltage change of 0.1 Hz.

Voltage drop Umi is composed of the superposition of changing line voltage U_{N} and square-pulse-shaped measuring voltage U_{G}. It can be clearly seen that the low-frequency line-voltage change dominates and thus exercises an interference on the measurement. According to the state of the art, an interference suppression is therefore required, e.g., via filtering. A measure of this kind for suppression of interferences, in particular one requiring much effort from a circuitry point of view in low-frequency line-voltage changes, can be foregone when applying the method according to the invention. Advantageously, the invention intends still detecting usable measured values even under these difficult conditions, i.e., with falsified measuring signals.

FIG. 5 shows a temporal progression of a computed insulation resistance Rf (as a total resistance of the parallel circuit of insulation resistances R₁ and R₂ in this instance) in a stepwise (trial-based) change of the real insulation resistance after 40 s under the condition of line voltage U_{N} characterized by the line-voltage change from FIG. 4.

About 20 s pass at first until computed insulation resistance Rf approximately corresponds to the real value. After the stepwise change of the real insulation resistance at the time of 40 s, about another 30 s pass until the measuring method provides the real value of the insulation resistance again.

FIG. 6 shows analogously to FIG. 5 a temporal progression of a computed leakage capacitance Ce (as the sum of leakage capacitances C₁ and C₂ in this instance) at a stepwise change of the real leakage capacitance after 40 s.

1. A method for determining an insulation resistance (R₁, R₂) and a leakage capacitance (C₁, C₂) against ground (PE) of an ungrounded DC power supply system, which has a line voltage (U_{N}) and active conductors (L₁, L₂), the method comprising the following method steps:
coupling (S1) a measuring voltage (U_{G}) in series to a measured resistance (R_{M}) in a unipolar or bipolar manner between one of the active conductors (L₁, L₂) and ground (PE) in each instance,
measuring (S2) a voltage drop (U_{M1}, U_{M2}) via the corresponding measured resistance (R_{M}),
generating (S3) time and value-discrete sample sequences (U_{G}(k), U_{N}(k), U_{M}(k)) of the measuring voltage (U_{G}), the line voltage (U_{N}) and the corresponding voltage drop (U_{M1}, U_{M2}),
implementing (S4) a linear difference equation having a measuring voltage (U_{M}(k)) as a function of the measuring voltage (U_{G}(k)) and the line voltage (U_{N}(k)) and having network parameters (θᵢ), which are formed from the measured resistances (R_{M}), from the insulation resistances to be determined (R₁, R₂) and from the leakage capacitances to be determined (C₁, C₂), implementing (S5) a measured-value equation system from N linear difference equations using the sample sequences (U_{G}(k), U_{N}(k), U_{M}(k)) and the network parameters (θᵢ) for k=1, 2 to N measuring points in time having the sampling period T,
computing (S6) estimated network parameters (\hat{θ}ᵢ) as an approximate solution of the measured-value equation system, a sum of squared residuals between the network parameters (θᵢ) and the estimated network parameters (θᵢ) being minimized,
minimizing (S7) the sum of squared residuals via QR decomposition of a measured-value matrix (Ψ), the QR decomposition being computed recursively,
computing (S8) the corresponding insulation resistance (R₁, R₂) and the corresponding leakage capacitance (C₁, C₂) from the estimated network parameters (\hat{θ}ᵢ),
continuously repeating the method steps having the correspondingly computed, estimated network parameters (\hat{θ}ᵢ) while taking into consideration the samples available for the current measuring point in time.

2. The method according to claim 1,
wherein
the linear difference equation is derived by transforming a linear algebraic equation in the frequency domain in a temporally continuous difference equation and its time-discrete implementation, the linear algebraic equation describing the current-voltage relationship.

3. The method according to claim 1,
wherein
the recursive QR decomposition is carried out based on a recursion matrix.

4. The method according to claim 1,
wherein
the QR decomposition is carried out by means of Givens rotation.

5. The method according to claim 1,
wherein
an upper triangular matrix (R) and a result vector (c) are weighted using a Forgetting Factor (\sqrt{λ}) in the recursive QR decomposition.
